(19) United States
(12) Patent Application Publication
(10) Pub. No.: US 2006/0097346 A1
(43) Pub. Date: May 11, 2006

(54) Structure for high quality factor inductor operation

(75) Inventor: Yin Yen Bong, Melaka (MY)

Correspondence Address: CONLEY ROSE, P.C., P. O. BOX 3267, HOUSTON, TX, 77253-3267, US

(73) Assignee: Advanpack Solutions Pte Ltd, Singapore (SG)

(21) Appl. No.: 10/985,186

(22) Filed: Nov. 10, 2004

(51) Int. Cl. H01L 29/00

(52) U.S. Cl. 257/531

(57) ABSTRACT

A structure for high quality factor inductor operation formed on a semiconductor chip is disclosed. The structure comprises a plurality of pillars displaced from the semiconductor chip for forming an inductor. The plurality of pillar is arranged in an electrically inductive formation and at least one of the plurality of pillars is electrically coupled to the semiconductor chip, wherein each of the plurality of pillars abuts at least one and no more than two adjacent pillars and is electrically communicable with the at least one and no more than two adjacent pillars.

### FIELD OF INVENTION

The invention relates generally to semiconductor devices. In particular, the invention relates to structures formed on a semiconductor chip for high quality factor inductor operation.

### BACKGROUND

Modern personal communication equipment such as mobile phones and other wireless devices are fast becoming indispensable tools for satisfying people's needs for mobile communication. Many of the communication equipment are based on radio frequency (RF) technology for transmitting and receiving communication signals. The communication signals are typically generated and received through radio frequency integrated circuits (RFICs).

Increasing demands for miniaturization of ICs, higher operating frequency and lower cost of manufacturing mean that the RFICs need to have higher packing density, better performing circuit components and manufacturability with common industrial processes and materials.

On-chip inductors are critical components of the RFICs and are widely used in low noise amplifiers (LNAs), voltage-controlled oscillators (VCOs) and impedance matching networks of the RFICs. Improving inductance performance of the on-chip inductors for attaining high quality factor or high Q-factor is therefore required in order to achieve RFICs with better operating performances.

Conventional on-chip inductors are typically fabricated horizontally on a semiconductor wafer and usually require a relatively large area of the semiconductor wafer for attaining sufficient inductance. The requirement of large area of the semiconductor wafer for fabricating the conventional on-chip inductors is undesirable for increasing the packing density of circuit components formed on the semiconductor wafer.

Additionally, the conventional on-chip inductors are usually made of thin metallization of a few micrometers (μm) thick. During operation, the conventional on-chip inductors produce magnetic and electric fields that penetrate undesirably into the semiconductor wafer, causing substrate losses and thereby reducing the Q-factor of the inductors. Furthermore, the thin metallization of the conventional on-chip inductors causes skin depth effect during high frequency operation. This causes high dynamic resistance, especially at gigahertz (GHz) frequency operation. The high dynamic resistance severely limits the high frequency performance of the conventional on-chip inductors.

One conventional method for reducing the substrate losses caused by the conventional on-chip inductors is disclosed in “Large Suspended Inductors on Silicon and their use in a 2-μm CMOS RF Amplifier”, by Chang et. al., IEEE Electron Device Lett., vol. 14, pp. 246-248, May 1993 and “High Q backside Micromachined CMOS Inductors”, by Ozgur et al., Proc. IEEE Intl. Symp. on Circuits and Systems, vol. 2, pp. 577-580, 1999. Both articles propose using etching techniques for removing portions of the semiconductor wafer on which the conventional on-chip inductors are fabricated. Although this method results in a reduction of the substrate losses, the method inevitably reduces mechanical stability and packaging yield of the RFICs.

Another conventional method for reducing the substrate losses caused by the conventional on-chip inductors is disclosed in “High Q Inductors for Wireless Applications in a Complementary Silicon Bipolar Process”, by Ashby et. al., IEEE J. Solid-State Circuits, vol. 31, pp. 4-9, January 1996. This method increases electrical resistivity of the semiconductor wafer on which the conventional on-chip inductors are fabricated. The increase in electrical resistivity of the semiconductor wafer significantly reduces the substrate losses caused by the conventional on-chip inductors. However, this method increases the difficulty of fabricating active deep sub-micrometer transistors on the semiconductor wafer due to a tighter requirement on circuit design rule as a result of the increase in electrical resistivity of the semiconductor wafer.

A method for improving high frequency inductor operation is disclosed in “A High Q RF CMOS Differential Active Inductor”, by Akbari-Dilmaghani et. al., Proc. IEEE Electronics, Circuits and Systems Conf., vol. 3, pp. 157-160, 1998. This method uses an active inductor for achieving high frequency inductor operation. However, the active inductor disclosed in the article requires high power consumption and has high noise levels. Additionally, the active inductor depends on a biasing circuit for proper operation, thereby increasing the need for more wafer area for fabricating the active inductor.

There is therefore a need for an on-chip inductor for attaining high Q-factor for improving high frequency operating performances and for reducing wafer area on which to fabricate the on-chip inductor.

### SUMMARY

Embodiments of the invention disclosed herein provide improved performance relating to high quality factor inductance. Additionally, the embodiments are suitable for reducing wafer area required for fabricating an on-chip inductor.

Therefore, in accordance with one aspect of the invention, a structure for high quality factor inductor operation formed on a semiconductor chip is disclosed. The structure comprises a plurality of pillars disposed on the semiconductor chip for forming an inductor. The plurality of pillar is arranged in an electrically inductive formation and at least one of the plurality of pillars is electrically coupled to the semiconductor chip, wherein each of the plurality of pillars abuts at least one and no more than two adjacent pillars and is electrically communicable with the at least one and no more than two adjacent pillars.

### BRIEF DESCRIPTION OF THE DRAWINGS

Embodiments of the invention are described hereinafter with reference to the drawings, in which:

FIG. 1 is a cross-sectional view of a structure for high quality factor inductor operation formed on a semiconductor chip;

FIG. 2 is a top view of the structure of FIG. 1, according to a first embodiment of the invention; and

FIG. 3 is a top view of the structure according to a second embodiment of the invention.

### DETAILED DESCRIPTION

With reference to the drawings, a structure according to embodiments of the invention for attaining high quality factor is disclosed for improving high frequency inductor operation.

Various conventional methods for improving high frequency inductor operation are disclosed herein. These conventional methods have limitations in packing density and packaging yield. Other conventional methods have difficulties fabricating active deep sub-micrometer transistors on semiconductor wafers due to a tighter requirement on circuit design rule as a result of an increase in electrical resistivity of the semiconductor wafers.

For purposes of brevity and clarity, the description of the invention is limited hereinafter to applications related to attaining high-Q factor inductor operation for radio frequency (RF) operation. This however does not preclude embodiments of the invention from other applications, such as optical networking or other wireless communication applications, which require similar operating performance as the applications for attaining high-Q factor inductor operation. The functional and operational principles on which the embodiments of the invention are based remain the same throughout the various embodiments.

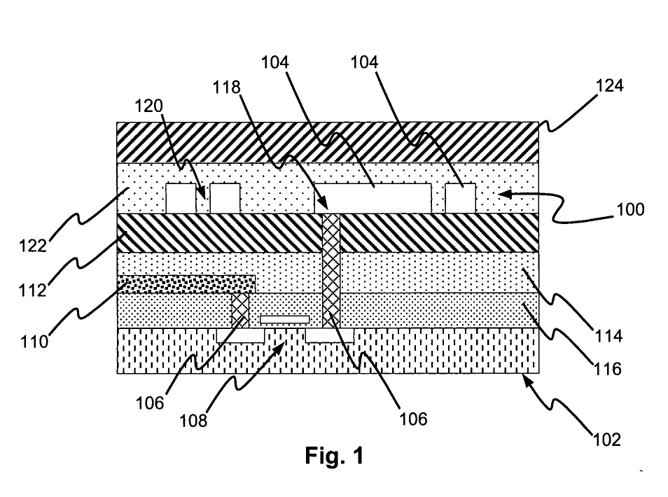

Embodiments of the invention are described in greater detail hereinafter for a structure for high-Q factor inductor operation formed on a semiconductor chip. In the detailed description and illustrations provided in FIGS. 1 to 3 of the drawings, like elements are identified with like reference numerals.

With reference to FIG. 1, a cross-sectional view of a structure 100 for high-Q factor inductor operation formed on a semiconductor chip 102 according to a first embodiment of the invention is shown. The structure 100 comprises a plurality of pillars 104 spatially displaced from the semiconductor chip 102 forming generally on a plane a polygonally shaped spiraling coil. Alternatively, the structure 100 is formed by at least one continuous pillar configured for high-Q factor inductor operation.

The structure 100 is designable by existing design software that uses circuit models for performance simulation and characteristics prediction. This advantageously allows the embodiments of the invention to be adopted in existing circuit design practices.

The semiconductor chip 102 is preferably a Very Large Scale Integration (VLSI) or Ultra Large Scale Integration (ULSI) integrated circuit (IC) having through holes, such as an interconnect via 106 of FIG. 1 for connecting the structure 100 to devices 108 formed in the semiconductor chip 102. Examples of such devices 108 are transistors, diodes and other microelectronic components. Some of the devices are connectable to a metal layer 110 by the interconnect via 106 for electrically communicating with other devices 108 formed in the semiconductor chip 102.

The plurality of pillars 104 is preferably formed on a passivation layer 112 of the semiconductor chip 102 and is preferably made of conductive material such as copper (Cu). The passivation layer 112 is preferably an insulator made of dielectric material, for example silicon dioxide (SiO₂) or silicon nitride (SiN). Having the structure 100 formed on the passivation layer 112 reduces wafer area needed for forming the IC, thereby allowing the semiconductor chip 102 to be smaller or attaining higher packing density.

As shown in FIG. 1, the interconnect via 106 is formed through the passivation layer 112 and other layers, such as inter-metallic dielectric layer 114 and field oxide layer 116, which are formed below the passivation layer 112. The interconnect via 106 allows the structure 100 to electrically communicate with the devices 108 formed in the semiconductor chip 102. The passivation layer 112 also separates the structure 100 and the devices 108 formed in the semiconductor chip 102 such that interference between the structure 100 and the devices 108 is considerably reduced.

Each of the plurality of pillars 104 is erected substantially upright and extends from the passivation layer 112 of the semiconductor chip 102. At least one of the plurality of pillars 104 has one end 118 thereof being electrically connected to the interconnect via 106. A bonding pad (not shown) is preferably formed on the passivation layer 112 for interfacing the pillar 104 and the interconnect via 106. The bonding pad is also used for connecting the IC to an external circuitry (not shown) through the use of connection means such as solder or pillars bumps. The solder or pillar bumps can be fabricated in conjunction with the structure 100.

Each of the plurality of pillars 104 preferably has substantially uniform longitudinal cross-sectional area. Each pillar 104 is connected to a nearest adjacent pillar and is preferably longitudinally elongated. The pillar 104 preferably has a predetermined height, such as but not limited to approximately 50 μm. The predetermined height of the pillars 104 ameliorates high frequency operation performances of the structure 100 by significantly reducing the presence of skin depth effect that is associated with thin inductors during high frequency operation.

The structure 100 is therefore capable of attaining high-Q factor and provides dependable inductance performances. This advantageously allows the structure 100 to be used in RF applications which requires high-Q factor inductor operation, such as but not limited to a stipulated operating frequency range of between 0.8 to 2.5 GHz.

As shown in FIG. 1, channels 120 between adjacent pillars 104 are preferably filled by a filler material 122 for minimizing parasitic capacitance present between the adjacent pillars 104 during high frequency operation thereof. The filler material 122 is preferably made of low dielectric constant (k) material and is provided through methods such as injection and reflowing. A protective layer 124 is optionally formable over the structure 100 for protecting the structure 100 from external elements such as moisture and particles that are present in the environment during packaging of the semiconductor chip 102.

The structure 100 is fabricated using common semiconductor processing methods and materials. The use of the structure 100 is compatible with small outline integrated circuit (SOIC) and dual in-line (DIL) packages and packaging processes such as flip-chip and wafer level packaging.

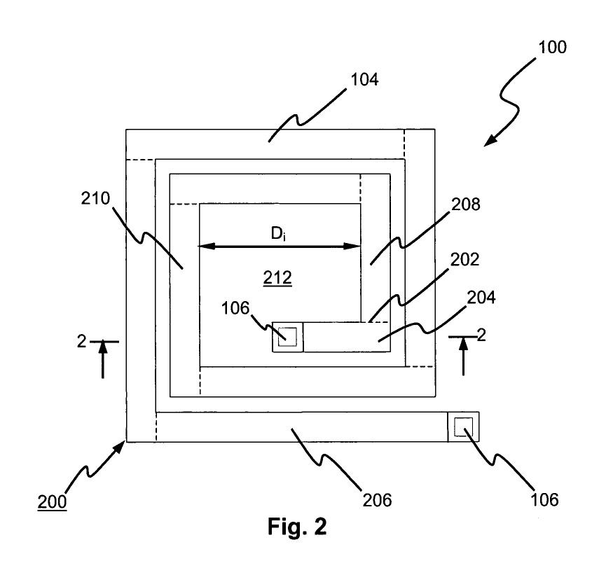

FIG. 2 shows a top view of the first embodiment of the invention, wherein FIG. 1 is the cross-sectional view of the structure 100 taken along line 2-2. The plurality of pillars 104 of the structure 100 of FIG. 1 is arranged in an electrically inductive formation 200, wherein each pillar 104 substantially orthogonally abuts at least one nearest adjacent pillar 104 along an interface 202 therebetween for forming the inductive formation 200. Each of the plurality of pillars 104 preferably has substantially uniform longitudinal and latitudinal cross-sectional areas. The inductive formation 200 is preferably a spiraling coil having a plurality of straight segments, in which the spiraling coil is substantially square.

An innermost pillar 204 and an outermost pillar 206 of the structure 100 are electrically connected to the devices 108 formed in the semiconductor chip 102 by through holes, such as the interconnect via 106 of FIG. 1. The innermost and outermost pillars 204 and 206 are preferably the respective ends of the structure 100.

The structure 100 has an inner diameter Di that is dependable on the dimensions of the pillars 104 that define the inner diameter Di. In this first embodiment of the invention, the distance between two opposing inner pillars 208 and 210 defines the inner diameter Di. The two opposing inner pillars 208 and 210 form two opposing sides of an inner square 212, wherein one of the two opposing inner pillars 208 abuts the innermost pillar 204 along the interface 202.

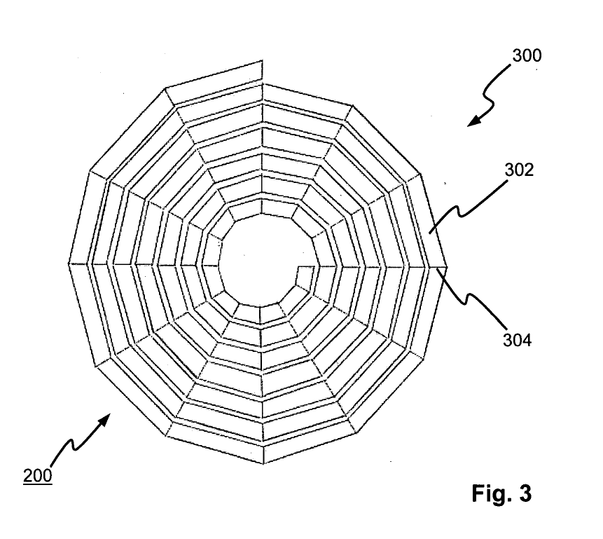

FIG. 3 shows a top view of a second embodiment of the invention, wherein the structure 300 comprises a plurality of pillars 302 is arranged substantially similar to the electrically inductive formation 200 of the first embodiment of the invention of FIG. 2. The plurality of pillars is arranged in a substantially twelve-sided polygonic spiraling coil such that each pillar 302 abuts at least one nearest adjacent pillar along an interface 304 therebetween for forming the inductive formation 200. The plurality of pillars 302 is preferably substantially trapezoidal and has substantially similar width.

In the various embodiments of the invention, the number of turns in the coil and the dimensions of the pillars are determined by the requirements of designing the IC.

In the foregoing manner, a structure for high quality factor inductor operation formed on a semiconductor chip is disclosed. Although only a number of embodiments of the invention are disclosed, it becomes apparent to one skilled in the art in view of this disclosure that numerous changes and/or modification can be made without departing from the scope and spirit of the invention. For example, although the structure is formed as a coil having a square or polygonic configuration in the forgoing embodiments, the structure may be efficiently performed if other polygonal or circular shape is used for forming the coil for providing the high quality factor inductor operation.

1. A structure for high quality factor inductor operation formed on a semiconductor chip, the structure comprising:
a plurality of pillars displaced from the semiconductor chip for forming an inductor, the plurality of pillar being arranged in an electrically inductive formation and at least one of the plurality of pillars being electrically coupled to the semiconductor chip,
wherein each of the plurality of pillars abuts at least one and not more than two adjacent pillars and is electrically communicable with the at least one and not more than two adjacent pillars.

2. The structure of claim 1, wherein the electrically inductive formation has a substantially coiled-shape.

3. The structure of claim 2, wherein the electrically inductive formation having a plurality of segments for forming a polygonally shaped spiraling coil.

4. The structure of claim 1, wherein the plurality of pillars is electrically communicable with devices formed in the semiconductor chip.

5. The structure of claim 1, wherein the plurality of pillars extends from the semiconductor chip and is erected substantially upright therefrom.

6. The structure of claim 1, wherein each of the plurality of pillars has substantially uniform longitudinal cross-sectional area.

7. The structure of claim 1, wherein the plurality of pillars is made from conductive material.

8. The structure of claim 7, wherein the conductive material is copper.

9. The structure of claim 1, wherein each of the plurality of pillars has at least a portion thereof abutting at least another of the plurality of pillars along the semiconductor chip for forming the electrically inductive formation.

10. The structure of claim 1, further comprising:
a layer of dielectric material formed on the semiconductor chip, wherein the layer of dielectric material passivates the structure.

11. The structure of claim 1, further comprising:
a filler material for filling channels formed between at least one pair of adjacent pillars, wherein the filler material reduces parasitic capacitance between the at least one pair of adjacent pillars.

12. The structure of claim 11, wherein the filler material is made of low dielectric constant material.

13. The structure of claim 1, wherein the at least one of the plurality of pillars being electrically communicable with an interconnect via formed in the semiconductor chip.

14. The structure of claim 13, wherein a bonding pad is provided between the at least one of the plurality of pillars and the interconnect via.

15. The structure of claim 14, further comprising:
a passivation layer, wherein the bonding pad is disposed on the passivation layer of the semiconductor chip.

16. The structure of claim 1, wherein the plurality of pillars has a predetermined height for improving high frequency operation performances.
